(19) United States
(12) Patent Application Publication
(10) Pub. No.: US 2015/0311356 A1
(43) Pub. Date: Oct. 29, 2015

(54) CRYSTALLINE SOLAR CELL AND METHOD FOR PRODUCING THE LATTER

(71) Applicants: Henning NAGEL, Freiburg (DE); Knut VAAS, Alzenau (DE); Wilfried SCHMIDT, Schwaigern (DE)

(72) Inventors: Henning NAGEL, Freiburg (DE); Knut VAAS, Alzenau (DE); Wilfried SCHMIDT, Schwaigern (DE)

(73) Assignee: SCHOTT SOLAR AG, Mainz (DE)

(21) Appl. No.: 13/821,203

(22) PCT Filed: Sep. 6, 2011
(86) PCT No.: PCT/EP11/65391

§ 371 Date: Jun. 19, 2013

(30) Foreign Application Priority Data
Sep. 6, 2010 (DE) 10 2010 037 355.9

(51) Int. Cl. H01L 31/028; H01L 31/0216; H01L 31/18; H01L 31/068

(52) U.S. Cl. CPC H01L 31/028; H01L 31/068; H01L 31/02168; H01L 31/1804; H01L 31/186

(57) ABSTRACT

A method for producing a crystalline solar cell having a p-doped silicon substrate with an n-doped region on the front side and also at least one antireflection layer is provided. The method includes uniformly applying a solution containing phosphoric acid to the entire front-side surface of the solar cell, forming phosphosilicate glass in a first thermal treatment step applied to the solar cell, and, in the first thermal treatment step or a subsequent thermal treatment step, forming silicon-containing precipitates near the surface with a homogeneous or substantially homogeneous surface coverage in a layer on the front-side surface of the substrate in the range of between 5% and 100%.

The invention relates to a crystalline solar cell having a p-doped silicon substrate with an n-doped region on the front side. The invention also relates to a method for producing a crystalline solar cell having a p-doped silicon substrate with an n-doped region on the front side and also at least one anti-reflection layer.

The n- and p-doped regions in a pn diode create a space charge zone, in which electrons migrate from the n layer into the p layer and holes migrate from the p layer into the n layer. If a voltage is applied to the metallic electrodes located on the n- and p-doped layers, a high current flows when the voltage at the negative electrode is negative. When the polarity is reversed, an appreciably lower current flows.

A special design of Si pn diodes are solar cells or photodetectors in which a portion of the front side is provided with an at least partially transparent layer, which generally has a reflection-reducing effect. Light penetrates through this layer into the silicon and is partially absorbed there. Excess electrons and holes are released in this way. The excess electrons migrate in the electric field of the space charge zone from the p-doped region to the n-doped region and finally to the metal contacts on the n-doped region; the excess holes migrate from the n-doped region into the p-doped region and finally to the metal contacts on the p-doped region. If a load is applied between the positive and negative electrodes, a current flows.

A large number of solar cells are usually connected in series by way of metallic connectors and laminated in a solar module comprising several layers of insulation to protect them from the influence of weathering. A problem is that, owing to the series connection of the solar cells and the series connection of a number of modules to form a system, system voltages of several hundred volts regularly arise. This results in strong electric fields between solar cells and ground potential, which lead to undesired displacement currents and leakage currents. As a result, charges can be deposited permanently on the surface of solar cells and thereby appreciably reduce the efficiency thereof. Charges can also accumulate on the surface under illumination or prolonged storage in the dark.

Known is the degradation of the open-circuit voltage and, to a lesser extent, also of the short-circuit current owing to charges on the front side of two-side-contacted silicon solar cells with n-type base doping and a p-doped front side (J. Zhao, J. Schmidt, A. Wang, G. Zhang, B. S. Richards, and M. A. Green, “Performance instability in n-type PERT silicon solar cells,” Proceedings of the 3^{rd} World Conference on Photovoltaic Solar Energy Conversion, 2003). Open-circuit voltage and short-circuit current are strongly degraded under illumination and prolonged storage in the dark. The accumulation of positive charges in the silicon nitride and/or silicon oxide on the front side was identified as the reason for the degradation. They lead to depletion of the silicon surface and thus to an increase in the surface recombination rate for minority charge carriers. It is characteristic that, as a result, the parallel resistance and thus the filling factor are not affected detrimentally.

The degradation of the open-circuit voltage and the short-circuit current owing to charges on the front side was observed also in the case of two-sided contacted silicon solar cells with an n-type base doping, an n-doped front side and a p-doped back side (J. Zhao, loc. cit.). They also degrade strongly under illumination and prolonged storage in the dark owing to the accumulation of negative charges in the silicon nitride and/or silicon oxide on the front side. In this case, the negative charges lead to depletion of the n-doped silicon surface and thus, once again, to an increase in the surface recombination rate. Characteristic in this case is also that the parallel resistance and thus the filling factor are not affected detrimentally.

For modules that contain back-side-contacted solar cells with n-type base doping, an n-doped front side, and local p- and n-doped regions on the back side of the substrate, degradation due to charges is known (see: R. Swanson, M. Cudzinovic, D. DeCeuster, V. Desai, J. Jürgens, N. Kaminar, W. Mulligan, L. Rodrigues-Barbosa, D. Rose, D. Smith, A. Terao, and K. Wilson, “The surface polarization effect in high-efficiency silicon solar cells,” Proceedings of the 15^{th} International Photovoltaic Science & Engineering Conference, p. 410, 2005; WO A 2007/022955; Philippe Welter, “Zu gute Zellen” [Toward Good Cells], Photon, p. 102, April 2006). If these modules have a high positive potential relative to ground, negative charges migrate onto the front side of the solar cells, at which no contacts are affixed. Because of the low electrical conductivity of the module assembly, they can remain there for a long time even after the system voltage has been disconnected. As a result, the surface recombination rate on the front side is increased and accordingly the open-circuit voltage and short-circuit current are reduced. Interestingly, a reduction in the filling factor has also been reported. No degradation occurs if the positive pole of the system is grounded, that is, if only negative system voltages are permitted a priori. Evidently, therefore, positive charges on the front side of this type of solar cell do not lead to any degradation. If degradation due to negative charges on the front side has already occurred, the degradation can be temporarily reversed by reversing the polarity of the system voltage in the dark or overnight, that is, by applying a high negative potential relative to ground (regeneration by means of compensating voltage). In this process, the negative charges flow away from the surface of solar cells. On the next day, however, the degradation recommences owing to high positive system voltage, so that the regeneration has to be repeated anew every night.

Further proposed in R. Swanson et al. (loc. cit.) for preventing the accumulation of charges on the front side of solar cells, in which all pn junctions and metal contacts are located on the back side of the substrate, is to apply a conductive coating onto the anti-reflection layer on the front side and to connect this coating conductively with the plus or minus pole of the solar cells on the back side.

Two-sided-contacted silicon solar cells with p-type base doping and an n-doped front side are appreciably less sensitive to changes in the surface recombination rate on the front side compared to the types of solar cells described above. For this reason, only minor degradation of the open-circuit voltage was found under illumination and prolonged storage in the dark (J. Zhao, loc. cit.).

In Ines Rutschmann, “Noch nicht ausgelernt” [Not yet fully learned], Photon, p. 122, January 2008, and Ines Rutschmann, “Polarisation überwunden” [Polarization Overcome], Photon, p. 124, August 2008, it is stated that modules containing two-sided-contacted silicon solar cells with p-type base doping and an n-doped front side exhibit low parallel resistances and thus also low filling factors after high negative system voltages have been applied. This is a sign of an interaction between emitter and base and is thus fundamentally different from the above-described effects on the surface recombination rate. Through treatment at elevated temperature and high humidity, the degraded modules partially regain their efficiency. At high positive system voltages, no degradation was found and modules that had already undergone degradation could be temporarily regenerated by applying a high positive potential relative to ground in the dark; that is, a regeneration by means of compensating voltage is also possible in this case, but with reversed polarity, as in the case of the above-described modules, which contain back-side-contacted solar cells side with n-type base doping, and an n-doped front side, and local p- and n-doped regions on the back side of the substrate. At high negative system voltages, the degradation resumes, so that the regeneration by means of compensating voltage has to be repeated regularly in this case as well. It is further reported that the degradation of modules at high negative system voltages is caused by the front-side metallization process used, a special transfer printing (see Rutschmann, loc. cit.).

Inferred from WO A 2010/068331 is a method to create regions having different doping concentration in the front-side region of a substrate of a solar cell, so as to produce a selective emitter.

The subject of DE A 10 2007 010 182 is a method for precision processing of substrates and the use thereof. For microstructuring thin layers, in particular, a phosphoric acid is used, which can be added to change the pH value, the wetting behavior, or the viscosity of acids or alkaline solutions, surfactants, or alcohols.

A glass containing phosphoric acid is used for doping semiconductor materials according to EP A 1 843 389.

Combined etching and doping media, which are suitable both for etching inorganic layers and for doping underlying layers, are described in DE A 101 50 040, the main field of application being p-doped silicon for the production of silicon solar cells.

The present invention is based on the problem of further developing a crystalline solar cell and a method for producing the latter such that the degradation of the parallel resistance and thus of the filling factor is reduced, in particular for two-sided-contacted silicon solar cells with p-type base doping, an n-doped front side, and an anti-reflection layer, owing to high negative system voltages or positive charges on the front side.

In accordance with the method, the problem is essentially solved in that, in the n-doped region of the p-doped silicon substrate, precipitates containing silicon are formed near the surface on the front side with a homogeneous or largely homogeneous surface coverage in the range of between 5% and 100%, with the entire front-side surface of the substrate being hydrophilized and a solution containing phosphoric acid then being applied uniformly onto the entire front-side surface and, subsequently, in a first thermal treatment step of the substrate, phosphosilicate glass is formed and, in the first thermal treatment step or in a subsequent second thermal treatment step, the silicon-containing precipitates near the surface are formed with homogeneous or largely homogeneous surface coverage.

The hydrophilization ensures that the desired, largely homogeneous surface coverage of the front-side surface of the solar cell occurs with the precipitates crystallized out of the SiₓP_{y} and SiₓP_{y}O_{z} phase by the thermal treatment.

Surprisingly, it has been found that when SiP precipitates are produced with a surface coverage of more than 5% near the surface and homogeneously in the n-doped layer, the degradation of the parallel resistance is prevented or at least strongly reduced. The precipitates are produced, in particular, by hydrophilization of the Si surface, a uniform coating with phosphoric acid, and subsequent thermal treatment. Hydrophilization is understood to mean the production of a thin oxide on the Si surface, so that the phosphoric acid that is subsequently applied wets the entire Si surface.

The hydrophilization of the Si surface can occur by immersing the Si wafers in an aqueous solution containing H₂O₂ or ozone. Ideally, a mixture of NaOH, water, and H₂O₂ is used in order to simultaneously remove porous silicon, which is formed in an often preceding acidic texturing. Alternatively, a mixture of hydrochloric acid, water, and H₂O₂ or sulfuric acid, water, and H₂O₂ can be used to simultaneously remove metallic impurities from the surface.

There is the further possibility of hydrophilizing the Si surface in a thermal treatment at temperatures above 300° C. in oxygen-containing atmosphere or by means of ozone-containing atmosphere. It is also advantageous to use UV light with wavelengths of less than 300 nm in oxygen-containing atmosphere.

The solution containing phosphoric acid is applied advantageously uniformly by means of immersion methods or by means of ultrasonic nebulization. In order to produce SiₓP_{y} and SiₓP_{y}O_{z} precipitates with the required surface coverage, the phosphorus concentration in the solution lies in the range of between 5% and 35%.

Furthermore, there is the possibility that, before the precipitates crystallize out, the phosphosilicate glass is removed by means of HF solution, for example.

An embodiment provides that the solution additionally contains small amounts of surfactant (preferably <1 vol %) or greater amounts of alcohol (preferably >5 vol %) in order to increase the wettability. This can occur alternatively to the hydrophilization, which is carried out prior to application of the solution containing phosphoric acid.

Therefore, the invention is characterized in that the solution containing phosphoric acid and containing the alcohol and/or surfactant is applied to the entire front-side surface.

At least one thermal treatment step is carried out at above 800° C. to produce the precipitates. Ideally, in a first temperature treatment step at above 900° C. for more than 2 min in oxygen-containing atmosphere, phosphosilicate glass is produced homogeneously on at least one side of the Si wafer and then, in a second thermal treatment step at above 820° C. for more than 15 min, silicon phosphide precipitates are formed. The phosphosilicate glass layer is created with a thickness in the range of 10 nm to 100 nm and should have a phosphorus concentration greater than 10 atomic percent. The phosphorus concentration in the silicon phosphide (SiₓP_{y}, SiₓPO_{z}) deposits is greater than 25 atomic percent.

In particular, it is provided that the first thermal treatment step for producing the phosphosilicate glass is carried out at a temperature T₁ of 800° C.≦T₁≦930° C. during a time t₁ of 2 min≦t₁≦90 min.

In a further development, the invention provides that the second thermal treatment step for producing the precipitates, that is, the silicon phosphide (SiₓP_{y}, SiₓP_{y}O_{z}) precipitates, is carried out at a temperature T₂ of 800° C.≦T₂≦930° C. during a time t₂ of 10 min≦t₂≦90 min.

If the phosphosilicate glass and the precipitates are crystallized out in a common thermal treatment step, the invention provides that the thermal treatment step is carried out at a temperature T₃ of 800° C.≦T₃≦930° C. during a time t₃ of 10 min≦t₃≦120 min.

In accordance with the invention, during doping of the p-conducting silicon substrate to form the n-doped front-side region, precipitates with a homogenous or largely homogeneous surface coverage are formed simultaneously in the front region of the n-doped region, with the surface coverage being 5% to 100% of the entire front surface of the n-doped region. Homogeneous surface coverage in this case means that the precipitates are distributed uniformly over the surface of the substrate, that is, its n-doped region.

Further details, advantages, and features of the invention ensue not only from the claims and the features taken from them, in themselves and/or in combination, but also from the following description of the preferred embodiment examples and the drawings.

Shown are:

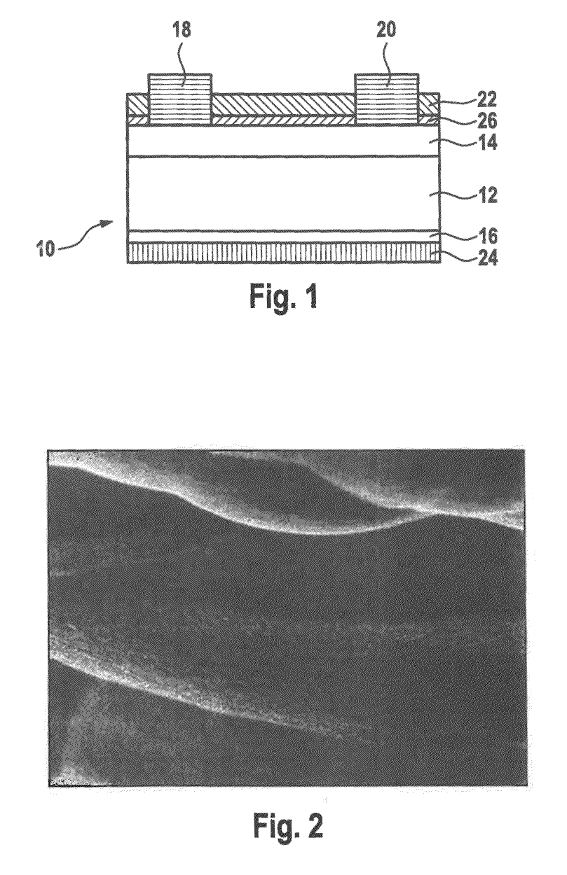

FIG. 1 an embodiment of the silicon solar cell with improved stability at high negative system voltages,

FIG. 2, 3 scanning electron micrographs of silicon-containing precipitates with a homogeneous surface coverage of greater than 6% on the Si surface,

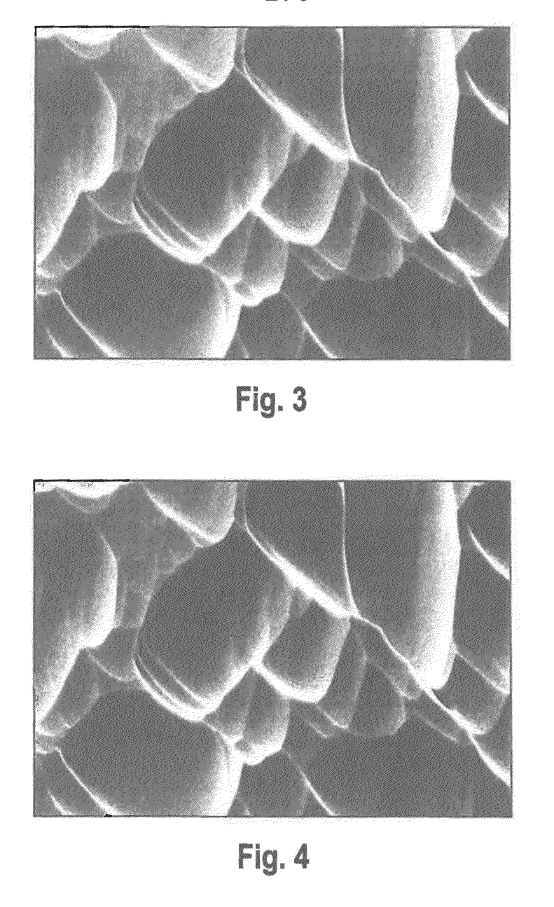

FIG. 4 a scanning electron micrograph of SiₓP_{y} precipitates with an inhomogeneous surface coverage, and

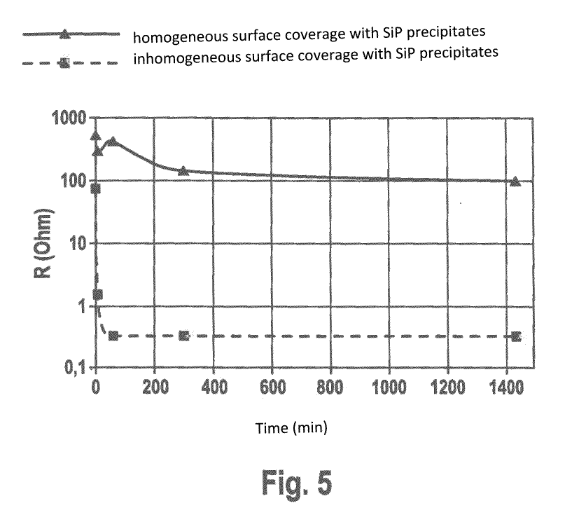

FIG. 5 measured parallel resistances of silicon solar cells with normal stability and improved stability at high negative system voltages as a function of the loading time with positive charges.

In the following description of preferred embodiment examples, it is assumed that the structure and function of a solar cell are adequately known, particularly in relation to p-doped crystalline silicon solar cells.

It should further be noted that the specified dimensionings are to be understood fundamentally as being given solely by way of example, without the teaching of the invention being hereby limited.

Illustrated in FIG. 1 in a simple basic diagram is a crystalline silicon solar cell 10. Said solar cell has a p-doped substrate 12 in the form of a 180-μm-thick silicon disc, for example, which is n⁺-doped on the front side, that is, over the entire front-side surface. The corresponding region is marked with reference 14. The substrate 12 is p⁺-diffused (region or layer 16) on the back side. Furthermore, strip-shaped or point-like front contacts 18, 20 are located on the front side. The front side of the solar cell has an anti-reflection layer 22 composed of silicon nitride, which, for example, can have a refractive index of 2.1. A back contact 24 is disposed on the entire surface on the back side.

In accordance with the invention, another silicon layer 26, referred to as a second layer, is disposed between the front-side or first silicon nitride layer 22 and the n⁺-diffused region 14, said second layer composed of a mixture of n⁺-diffused crystalline silicon and precipitates crystallized out of the SiₓP_{y} or SiₓP_{y}O_{z} phase, which are simply referred to as silicon phosphide precipitates.

The layer 26, also referred to as a second layer, is formed during doping of the p-doped substrate 12, in that, in accordance with the invention, the phosphoric acid-containing solution needed for the n-doping is applied uniformly onto the entire front-side surface of the substrate 12 so as then to form phosphosilicate glass in a first thermal treatment step and, in the first thermal treatment step or in a subsequent second thermal treatment step, the silicon-containing precipitates near the surface, which are uniformly distributed and form in the front-side surface of the substrate 12, with it being possible for the homogeneous or substantially homogeneous surface coverage to lie between 5% and 100% depending on the process parameters. The uniform distribution of the homogeneous or largely homogeneous surface coverage is made possible by hydrophilizing the entire surface of the front side of the substrate. This occurs before application of the solution containing phosphoric acid. If need be, moreover, alcohol and/or surfactant can be added to the solution containing phosphoric acid to support or enhance the uniform wetting of the solution containing phosphoric acid over the entire front-side surface of the substrate 12.

As a result of the formation of the intermediate layer 26 between the anti-reflection layer 22 and the n⁺ region 14, a degradation of the parallel resistance to the pn junction, which exists between the layers 12, 14, is prevented or strongly reduced. The intermediate layer 26 that is formed during production of the n⁺-doped layer, that is, the surface region of the n⁺-doped layer, exhibits a lower electrical conductivity than the n⁺-doped Si layer without precipitates.

As can be seen from FIG. 1, the front contacts 18, 20 pass through not only the anti-reflection layer 22, but also the surface region of the n⁺ layer 14, that is, the layer 26, in which the precipitates have been formed with a homogeneous, that is, uniform, distribution over the surface. To this end, a glass-containing metallization paste is applied to the anti-reflection layer 22 by means of silk-screen printing, for example, so as then to carry out baking during subsequent thermal treatment (sintering) at a temperature of greater than 750° C. and for a time of more than 3 sec.

The scanning electron micrographs in FIGS. 2 and 3 show a homogeneous coverage of the Si surface with needle-shaped silicon phosphide precipitates with an area percent of greater than 6%. The surface coverage is an important measure of the electrical resistance of the intermediate layer 26. Illustrated in the scanning electron micrograph of FIG. 4 is an intermediate layer with inhomogeneous coverage of the Si surface with silicon phosphide precipitates. Wherever there is little or no silicon phosphide precipitate, the electrical conductivity is increased and degradation of the parallel resistance occurs.

Degradation of the parallel resistance must be prevented, because, when the parallel resistance decreases too much, a virtual short circuit in the pn junction occurs, so that the solar cell can no longer function properly.

FIG. 5 shows, by way of example, the parallel resistances of two solar cells, in which the positive charge was introduced onto the surface by means of corona discharge, as a function of time. The two solar cells have silicon phosphide precipitates on the surface. However, the homogeneity of the surface coverage with silicon phosphide precipitates varies. It can be seen from FIG. 5 that the parallel resistance of the solar cell with homogeneously formed intermediate layer is markedly more stable and has values of greater than 100 ohm over the entire time range investigated, whereas the parallel resistance of the solar cell with inhomogeneous surface coverage of the precipitates has dropped to below 2 ohm even after 10 min.

1-23. (canceled)

24. A method for producing a crystalline solar cell having a p-doped silicon substrate with an n-doped region on a front side and at least one anti-reflection layer, comprising:
forming, in the n-doped region of the substrate, precipitates containing silicon near a front-side surface with a homogeneous or largely homogeneous surface coverage in the range of between 5% and 100%,
hydrophilizing an entirety of the front-side surface of the p-doped silicon substrate and then applying a solution containing phosphoric acid uniformly onto the entire front-side surface and,
subsequently forming, in a first thermal treatment step of the substrate, phosphosilicate glass,
wherein in the first thermal treatment step or in a subsequent second thermal treatment step the precipitates containing silicon are formed near the front-side surface.

25. The method according to claim 24, further comprising adding a component to the solution containing phosphorus before applying the solution containing phosphorus to the entire front-side surface, the component being selected from the group consisting of a surfactant in less than 1 vol %, or alcohol in greater than 5 vol %, and combinations thereof.

26. The method according to claim 24, wherein the step of hydrophilizing the entirety of the front-side surface of the p-doped silicon substrate comprises wet-chemically hydrophilizing in an H₂O₂ or ozone-containing solution.

27. The method according to claim 24, wherein the step of hydrophilizing the entirety of the front-side surface of the p-doped silicon substrate comprises wet-chemically hydrophilizing in a mixture of NaOH and H₂O₂.

28. The method according to claim 24, wherein the step of hydrophilizing the entirety of the front-side surface of the p-doped silicon substrate comprises wet-chemically hydrophilizing a thermal treatment at temperatures above 300° C. in oxygen-containing atmosphere.

29. The method according to claim 24, wherein the step of hydrophilizing the entirety of the front-side surface of the p-doped silicon substrate comprises wet-chemically hydrophilizing in an ozone-containing atmosphere.

30. The method according to claim 24, wherein the step of hydrophilizing the entirety of the front-side surface of the p-doped silicon substrate comprises wet-chemically hydrophilizing via UV light with wavelengths of less than 300 nm in an oxygen-containing atmosphere.

31. The method according to claim 24, wherein the solution containing phosphorus is applied by an immersion method or an ultrasonic nebulization.

32. The method according to claim 24, wherein the solution containing phosphorus comprises a phosphoric acid concentration in a range of between 5% and 35%.

33. The method according to claim 24, wherein the first thermal treatment comprises a temperature of greater than or equal to 800° C. and less than or equal to 930° C. for a time of greater than or equal to 2 minutes and less than or equal to 90 minutes.

34. The method according to claim 24, wherein the second thermal treatment comprises a temperature of greater than or equal to 800° C. and less than or equal to 930° C. for a time of greater than or equal to 10 minutes and less than or equal to 90 minutes.

35. The method according to claim 24, wherein the first and second thermal treatment step comprise a common thermal treatment step having a temperature of greater than or equal to 800° C. and less than or equal to 930° C. for a time of greater than or equal to 10 minutes and less than or equal to 120 minutes.

36. The method according to claim 24, wherein the first thermal treatment comprises thermal treatment under an oxygen-containing atmosphere.

37. The method according to claim 24, further comprising removing the phosphosilicate glass prior to the second thermal treatment step.

38. The method according to claim 24, wherein the phosphosilicate glass comprises a layer with a thickness in the range of between 10 nm and 100 nm.

39. The method according to claim 24, wherein the phosphosilicate glass comprises a layer with a phosphorus concentration greater than 10%.

40. The method according to claim 24, wherein the step of forming the precipitates comprises crystallizing out the precipitate with a phosphorus concentration of greater than 25 atomic percent.

41. The method according to claim 24, wherein the precipitates are crystallized out homogeneously so that the precipitates crystallized out per unit area vary from one unit area to another by less than 15%.

42. A crystalline solar cell with a p-doped Si substrate comprising a front-side n-doped region having silicon-containing precipitates near a surface with a homogeneously or substantially homogeneously surface coverage in a range of 5% to 100%.

43. The crystalline solar cell according to claim 42, wherein the silicon-containing precipitates vary from one unit area to another by less than 15%.

44. The crystalline solar cell according to claim 42, further comprising an area-averaged specific electrical resistance of a layer of up to 100 nm in thickness near the surface in the front-side n-doped region, with the precipitates crystallized out of the SiₓP_{y} or SiₓP_{y}O_{z} phase, is about 5 Ωcm with a surface coverage of 100%.

45. The crystalline solar cell according to claim 42, wherein the precipitates are crystallized out with a phosphorus concentration of greater than 25%.
